(19) United States
(12) Patent Application Publication
(10) Pub. No.: US 2026/0143626 A1
(43) Pub. Date: May 21, 2026

(54) METHOD OF ENABLING A REMOTE HEATSINK USING A THERMOACOUSTIC HEAT PUMP IN A COMPUTING DEVICE

(71) Applicant: Lenovo Global Technology (United States) Inc., Morrisville, NC (US)

(72) Inventors: Arvind Modekurti, Cary, NC (US); Jeffrey S. Holland, Newton, NC (US)

(21) Appl. No.: 18/950,595

(22) Filed: Nov. 18, 2024

(51) Int. Cl. H05K 7/20; F25B 9/14

(52) U.S. Cl. CPC H05K 7/20163; F25B 9/145; H05K 7/20481; F25B 2309/1403

(57) ABSTRACT

An apparatus includes a heat sink and a resonance tube in a computing device extending from a fan and past the heat sink and past a component of the computing device. The resonance tube is thermally coupled to the heat sink and to the component. The apparatus includes a driver connected at an end of the resonance tube adjacent to the fan. Sound from the fan moves the driver to induce sound waves within the resonance tube. A length of the resonance tube is selected to correspond to a fan sound frequency of sound emanating from the fan where sound waves at the frequency resonate within the resonance tube at the fan sound frequency. Heat from the component is transferred to the resonance tube and travels in the resonance tube to a location where the heat sink is coupled to the resonance tube and exits to the heat sink.

### FIELD

The subject matter disclosed herein relates to cooling of a computing device and more particularly relates to using a thermoacoustic heat pump to cool components of a computing device.

### BACKGROUND

Acoustic noise or sound energy generated by cooling fans in computing devices is unavoidable, although efforts are being made in the design to mitigate the sound energy as much as possible. A higher acoustic noise is often considered as an inefficiency in the fan design along with heat dissipated by the motor.

### BRIEF SUMMARY

An apparatus with a thermoacoustic heat pump driven by sound from a fan of a computing device includes a heat sink in a computing device and a resonance tube in the computing device extending from the fan and past the heat sink and past a component of the computing device. The resonance tube is thermally coupled to the heat sink and to the component. The apparatus includes a driver connected at an end of the resonance tube adjacent to the fan. The driver is configured such that sound from the fan moves the driver to induce sound waves within the resonance tube. A length of the resonance tube is selected to correspond to a fan sound frequency of sound emanating from the fan where sound waves at the fan sound frequency resonate within the resonance tube at the fan sound frequency. Heat from the component is transferred to the resonance tube and travels in the resonance tube to a location where the heat sink is coupled to the resonance tube and exits to the heat sink.

Another apparatus with a thermoacoustic heat pump driven by sound from a fan of a computing device includes a heat sink in a computing device and a resonance tube in the computing device extending from the fan and past the heat sink and past a component of the computing device. The resonance tube is thermally coupled to the heat sink and to the component. The apparatus includes a driver connected at an end of the resonance tube adjacent to the fan. The driver is configured such that sound from the fan moves the driver to induce sound waves within the resonance tube. The apparatus includes a cold heat exchanger within the resonance tube at a component location where the component is coupled to the resonance tube, a hot heat exchanger within the resonance tube at a heat sink location where the heat sink is coupled to the resonance tube, and a stack within the resonance tube spanning between the cold heat exchanger and the hot heat exchanger. The cold heat exchanger, the hot heat exchanger, and the stack each include a porous material configured to transfer heat. A length of the resonance tube is selected to correspond to a fan sound frequency of sound emanating from the fan where sound waves at the fan sound frequency resonate within the resonance tube at the fan sound frequency. Heat from the component is transferred to the resonance tube and travels in the resonance tube to a location where the heat sink is coupled to the resonance tube and exits to the heat sink.

A system with a thermoacoustic heat pump includes a computing device with a processor, a fan configured to provide cooling to the processor, a component within the computing device, a heat sink within the computing device, and a resonance tube in the computing device extending from the fan and past the heat sink and past the component of the computing device. The resonance tube is thermally coupled to the heat sink and to the component. The system includes a driver connected at an end of the resonance tube adjacent to the fan. The driver is configured such that sound from the fan moves the driver to induce sound waves within the resonance tube. A length of the resonance tube is selected to correspond to a fan sound frequency of sound emanating from the fan, where sound waves at the fan sound frequency resonate within the resonance tube at the fan sound frequency. Heat from the component is transferred to the resonance tube and travels in the resonance tube to a location where the heat sink is coupled to the resonance tube and exits to the heat sink.

### BRIEF DESCRIPTION OF THE DRAWINGS

A more particular description of the embodiments briefly described above will be rendered by reference to specific embodiments that are illustrated in the appended drawings. Understanding that these drawings depict only some embodiments and are not therefore to be considered to be limiting of scope, the embodiments will be described and explained with additional specificity and detail through the use of the accompanying drawings, in which:

FIG. 1 is a schematic block diagram illustrating a thermoacoustic heat pump driven by sound from a fan of a computing device, according to various embodiments;

FIG. 2 is a schematic block diagram illustrating the thermoacoustic heat pump of FIG. 1 applied to a server, according to various embodiments;

FIG. 3 is a schematic block diagram illustrating a side view of the thermoacoustic heat pump of FIG. 2, according to various embodiments;

FIG. 4 is a schematic block diagram illustrating a cross section view of stack designs of various thermoacoustic pumps, according to various embodiments;

FIG. 5 is a schematic block diagram illustrating a cross section view of a driver for a thermoacoustic heat pump driven by sound of a fan, according to various embodiments; and

FIG. 6 is a schematic block diagram illustrating another thermoacoustic heat pump driven by sound from a fan computing device where the thermoacoustic heat pump includes a hemispherical end, according to various embodiments.

### DETAILED DESCRIPTION

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art will recognize, however, that the invention may be practiced without one or more of the specific details, or with other methods, components, materials, and so forth. In other instances, well-known structures, materials, or operations are not shown or described in detail to avoid obscuring aspects of the invention.

The description of elements in each figure may refer to elements of proceeding figures. Like numbers refer to like elements in all figures, including alternate embodiments of like elements.

As used herein, a list with a conjunction of “and/or” includes any single item in the list or a combination of items in the list. For example, a list of A, B and/or C includes only A, only B, only C, a combination of A and B, a combination of B and C, a combination of A and C or a combination of A, B and C. As used herein, a list using the terminology “one or more of” includes any single item in the list or a combination of items in the list. For example, one or more of A, B and C includes only A, only B, only C, a combination of A and B, a combination of B and C, a combination of A and C or a combination of A, B and C. As used herein, a list using the terminology “one of” includes one and only one of any single item in the list. For example, “one of A, B and C” includes only A, only B or only C and excludes combinations of A, B and C.

An apparatus with a thermoacoustic heat pump driven by sound from a fan of a computing device includes a heat sink in a computing device and a resonance tube in the computing device extending from the fan and past the heat sink and past a component of the computing device. The resonance tube is thermally coupled to the heat sink and to the component. The apparatus includes a driver connected at an end of the resonance tube adjacent to the fan. The driver is configured such that sound from the fan moves the driver to induce sound waves within the resonance tube. A length of the resonance tube is selected to correspond to a fan sound frequency of sound emanating from the fan where sound waves at the fan sound frequency resonate within the resonance tube at the fan sound frequency. Heat from the component is transferred to the resonance tube and travels in the resonance tube to a location where the heat sink is coupled to the resonance tube and exits to the heat sink.

In some embodiments, the heat sink is positioned within an air flow within the computing device. The air flow is configured to stream across the heat sink. In other embodiments, the air flow across the heat sink originates at the fan. In other embodiments, the apparatus includes a cold heat exchanger within the resonance tube at a component location where the component is coupled to the resonance tube, a hot heat exchanger within the resonance tube at a heat sink location where the heat sink is coupled to the resonance tube, and a stack within the resonance tube spanning between the cold heat exchanger and the hot heat exchanger. The cold heat exchanger, the hot heat exchanger, and the stack each include a porous material configured to transfer heat.

In other embodiments, the porous materials of the cold heat exchanger, the hot heat exchanger, and the stack each include channels where the channels run in a direction of the length of the resonance tube. In other embodiments, the porous materials of the cold heat exchanger, the hot heat exchanger, and the stack include parallel plates, spiral sheets, rectangular pores, a pin array, a honeycomb, and/or a random array. Spaces within the porous material form the channels. In other embodiments, the porous materials of the cold heat exchanger, the hot heat exchanger, and the stack include plastic, reticulated vitreous carbon (“RVC”) foam, mylar, copper, nickel, stainless steel, molybdenum, tungsten, Kapton, Celcor, high impact poly styrene (“HIPS”), polyamid nylon (“PA”), and/or acrylonitrile butadiene styrene (“ABS”).

In some embodiments, the component includes a hard disk drive, a solid-state drive, a memory card, or a network interface card. In other embodiments, the resonance tube includes a gas within the resonance tube. In other embodiments, the gas is air, helium, or nitrogen. In other embodiments, the driver includes a diaphragm. In other embodiments, the driver is adjacent to the fan and the resonance tube extends from the driver to the heat sink and from the heat sink to the component and from the component to a closed end. In other embodiments, a distance from the closed end to the component is chosen so the length of the resonance tube corresponds to a resonant frequency of the sound waves in the resonance tube induced by the fan sound frequency. In other embodiments, the closed end of the resonance tube is shaped to reflect the sound waves in the resonance tube. In other embodiments, the component is located in an area of lower air flow than air flow across the heat sink.

Another apparatus with a thermoacoustic heat pump driven by sound from a fan of a computing device includes a heat sink in a computing device and a resonance tube in the computing device extending from the fan and past the heat sink and past a component of the computing device. The resonance tube is thermally coupled to the heat sink and to the component. The apparatus includes a driver connected at an end of the resonance tube adjacent to the fan. The driver is configured such that sound from the fan moves the driver to induce sound waves within the resonance tube. The apparatus includes a cold heat exchanger within the resonance tube at a component location where the component is coupled to the resonance tube, a hot heat exchanger within the resonance tube at a heat sink location where the heat sink is coupled to the resonance tube, and a stack within the resonance tube spanning between the cold heat exchanger and the hot heat exchanger. The cold heat exchanger, the hot heat exchanger, and the stack each include a porous material configured to transfer heat. A length of the resonance tube is selected to correspond to a fan sound frequency of sound emanating from the fan where sound waves at the fan sound frequency resonate within the resonance tube at the fan sound frequency. Heat from the component is transferred to the resonance tube and travels in the resonance tube to a location where the heat sink is coupled to the resonance tube and exits to the heat sink.

In some embodiments, the heat sink is positioned within an air flow within the computing device and the air flow is configured to stream across the heat sink. In other embodiments, the porous materials of the cold heat exchanger, the hot heat exchanger, and the stack each include channels where the channels run in a direction of the length of the resonance tube.

A system with a thermoacoustic heat pump includes a computing device with a processor, a fan configured to provide cooling to the processor, a component within the computing device, a heat sink within the computing device, and a resonance tube in the computing device extending from the fan and past the heat sink and past the component of the computing device. The resonance tube is thermally coupled to the heat sink and to the component. The system includes a driver connected at an end of the resonance tube adjacent to the fan. The driver is configured such that sound from the fan moves the driver to induce sound waves within the resonance tube. A length of the resonance tube is selected to correspond to a fan sound frequency of sound emanating from the fan, where sound waves at the fan sound frequency resonate within the resonance tube at the fan sound frequency. Heat from the component is transferred to the resonance tube and travels in the resonance tube to a location where the heat sink is coupled to the resonance tube and exits to the heat sink.

In some embodiments, the heat sink is positioned within an air flow within the computing device where the air flow is configured to stream across the heat sink. In other embodiments, the air flow across the heat sink originates at the fan.

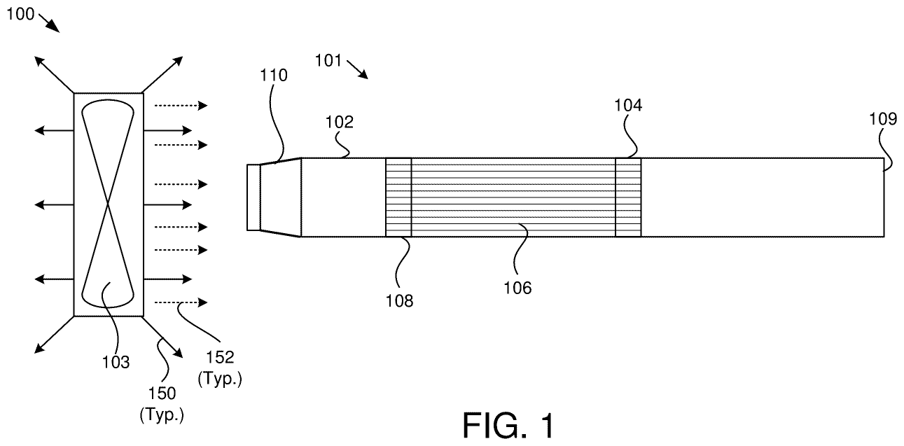

FIG. 1 is a schematic block diagram 100 illustrating a thermoacoustic heat pump 101 driven by sound from a fan 103 of a computing device 106, according to various embodiments. The thermoacoustic heat pump 101 includes a resonance tube 102 with a cold heat exchanger 104, a stack 106, a hot heat exchanger 108, a closed end 109 with a reflective surface at a first end of the resonance tube 102 and a driver 110 at a second end of the resonance tube 102. A fan 103 of a computing device produces sound waves 150 in various directions and is positioned to create air flow 152 towards the driver 110 of the thermoacoustic heat pump 101 along with other components of a computing device.

For the thermoacoustic heat pump 101 of FIG. 1, the sound waves 150 emanating from the fan 103 interact with the driver 110 to induce sound waves within the resonance tube 102, and within a gas interior to the resonance tube 102. The induced sound waves result in parcels of the gas in the resonance tube 102 adiabatically alternatively compressing and expanding so that pressure and temperature change simultaneously. When pressure reaches a maximum or a minimum, the temperature also reaches a maximum or a maximum, respectively. In the resonance tube 102, two sound waves traveling in opposite directions generate interference at particular frequencies. The interference causes resonance and creates a standing wave.

The stack 106 typically spans between the cold heat exchanger 104 and the hot heat exchanger 108. The stack 106, the cold heat exchanger 104, and/or the hot heat exchanger 108, in some embodiments, includes a porous material configured to transfer heat. In some embodiments, the porous materials of the cold heat exchanger 104, the hot heat exchanger 108, and/or the stack 106 each include small parallel channels running in a direction of the length of the resonance tube 102. The stack 106 is placed at a particular location in the resonance tube 102 having a standing wave, a temperature differential develops across the stack 106. The cold heat exchanger 104 and the hot heat exchanger 108 are placed at either end of the stack 106 so that heat is moved from the cold heat exchanger 104 to the hot heat exchanger 108. The thermoacoustic heat pump 101 could also be reversed so that heat input at the hot heat exchanger 108 and removed at the cold heat exchanger 104 could set up a sound wave to drive a sound output at the driver 110. In this instance, the resonance tube 102 becomes a prime mover instead of a heat pump.

The cold heat exchanger 104 is coupled to a component in the computing device to remove heat from the component. The hot heat exchanger 108 is connected to a heat sink of some type to radiate heat away from the heat sink. In some embodiments, the heat sink is placed in the air stream 152 of the fan 103 to remove heat from the heat sink. In the embodiments described herein, sound waves 150 from the fan 103 are used to input sound at the driver 110. In some embodiments, the driver 110 includes a diaphragm set up to vibrate and to transfer sound energy from the sound waves 150 hitting the diaphragm to the gas of the resonance tube 102.

For the thermoacoustic heat pump 101 functioning as a heat pump, creating or moving heat from a cold reservoir to a warm reservoir requires work. Acoustic power of the thermoacoustic heat pump 101 provides the work. The stack 106 creates a pressure drop across the stack 106. The interference between the incoming and reflected acoustic waves becomes imperfect due to the pressure drop and the difference in amplitude causes the standing wave to travel, which provides the acoustic power.

The heat pumping action along the stack in a standing wave follows the Brayton cycle, which can be described as four processes that affect a parcel of gas between two plates of the stack 106:
1. Adiabatic compression of the gas. When a parcel of gas is displaced from a right position (towards the cold heat exchanger 104) to a right position (towards the hot heat exchanger 108), the parcel is adiabatically compressed, which increases the parcel's temperature. At the hot heat exchanger 108, the parcel is hotter than the hot heat exchanger 108.
2. Isobaric heat transfer. The parcel's higher temperature than the hot heat exchanger 108 causes heat transfer to the hot heat exchanger 108 at a constant pressure, which cools the gas.
3. Adiabatic expansion of the gas. The gas is displaced back from the hot heat exchanger 108 to the cold heat exchanger 104. Due to adiabatic expansion, the gas cools to a temperature lower than the cold heat exchanger 104.
4. Isobaric heat transfer. The parcel's temperature being lower than the cold heat exchanger 104 causes heat to be transferred from the cold heat exchanger 104 to the parcel of gas at a constant pressure, returning the parcel's temperature back to the original value.

Typically, both prime movers (e.g., engines) and heat pumps use stacks. There is a boundary between a prime mover and a heat pump given by a temperature gradient operator I, which is a mean temperature gradient ∇Tₘ divided by a critical temperature gradient ∇T_{crit}:

$$I = \frac{∇ {T}_{m}}{∇ {T}_{crit}} \qquad ( 1 )$$

The mean temperature gradient ∇Tₘ from equation (1) is the temperature difference across the stack ΔTₘ divided by the length of the stack Δx_{stack}:

$$∇ {T}_{m} = \frac{Δ {T}_{m}}{Δ {x}_{stack}} \qquad ( 2 )$$

The critical temperature gradient ∇T_{crit} of equation (1) is dependent on characteristics of the thermoacoustic heat pump 101, such as frequency, cross-sectional area, gas properties, etc. If the temperature gradient operator/exceeds a value of one, the mean temperature gradient ∇Tₘ is larger than the critical temperature gradient ∇T_{crit} and the stack 106 operates as a prime mover. If the temperature gradient operator/is less than one, the mean temperature gradient ∇Tₘ is smaller than the critical temperature gradient ∇T_{crit} and the stack 106 operates as a heat pump.

The length of the resonance tube 102 is selected to achieve resonance for a particular fan sound frequency, which in the case of the thermoacoustic heat pump 101 of FIG. 1 is a fan sound frequency generated by the sound emanating from the fan 103. In some embodiments, the frequency is chosen as a dominant fan sound frequency of the fan 103. In other embodiments, the frequency is chosen as one of the dominant frequencies generated by sound from the fan 103 along with design considerations associated with possible lengths of the resonance tube 102, available space in the chassis of the computing device, and the like. The closed end 109, in some embodiments, is a flat surface or other shape designed to reflect sound waves at the first end of the resonance tube 102.

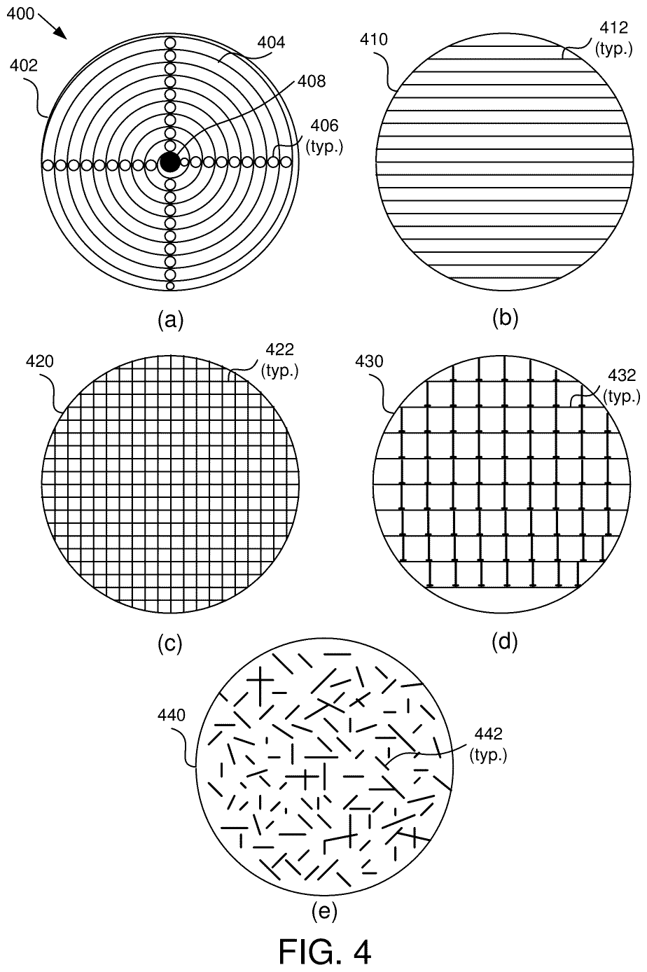

The cold heat exchanger 104 and/or the hot heat exchanger 108 include a material that is able to transmit heat. In some embodiments, the material is copper, molybdenum, stainless steel, tungsten, tin, or other metal or material that is able to transmit heat. In some embodiments, the cold heat exchanger 104 and/or the hot heat exchanger 108 are shaped have openings that match the channels of the stack 106 to allow sound waves to be transmitted through the cold heat exchanger 104 and/or the hot heat exchanger 108. Discussion of various potential shapes for the stack 106 is below in relation to FIG. 4.

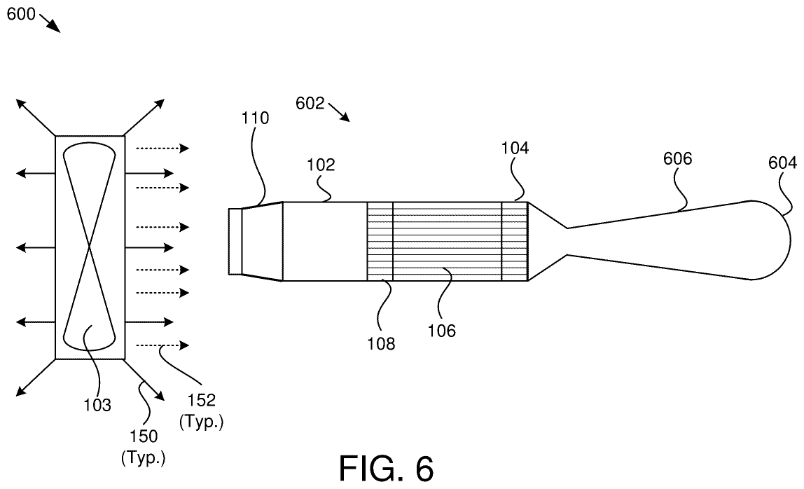

While the resonance tube 102 is depicted as round and cylindrical, in other embodiments, the resonance tube 102 is shaped differently. In some embodiments, the resonance tube 102 has a cross section that is square, oval, rectangular, etc. in some embodiments, the shape of the resonance tube 102 beyond the cold heat exchanger 104 is another shape, as described in FIG. 6.

The gas within the resonance tube 102 may vary depending on design considerations. In various embodiments, the gas may be air, helium, nitrogen, or other inert gas known to those of skill in the art to be suitable for a thermoacoustic heat pump 101.

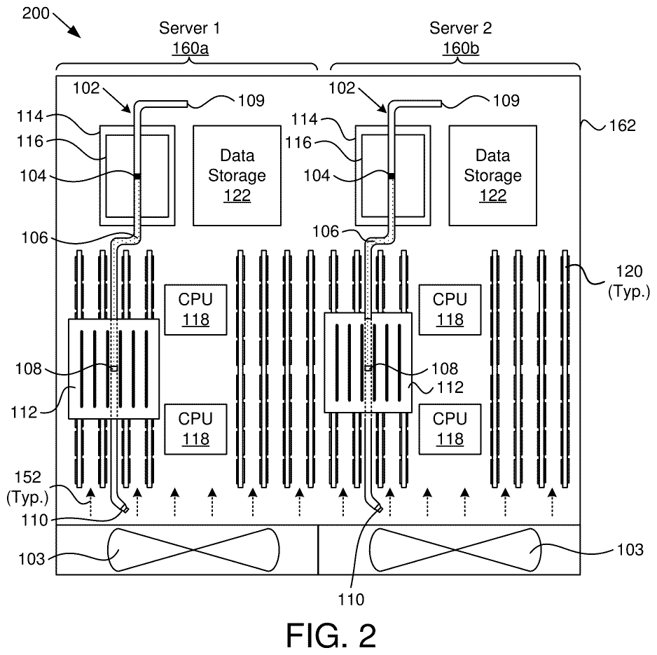

FIG. 2 is a schematic block diagram 200 illustrating the thermoacoustic heat pump 101 of FIG. 1 applied to servers 160a, 160b, according to various embodiments. The servers 160a, 160b (generically or collectively “160”) share a common motherboard 162 and include two thermoacoustic heat pumps 101, each cooling a component 114 and transferring heat to a heat sink 112 at a heat sink location over dual inline memory modules (“DIMMs”) 120. The servers 160 include fans 103 where air flow of the fans 103 travel past the DIMMs 120 and the heat sinks 112. The components 114 being cooled each include a heat spreader 116, or similar device coupled to a top of the components 114 and to the cold heat exchanger 104. The heat spreader 116 is designed to allow heat from the components 114 to be transferred to the cold heat exchanger 104.

The hot heat exchangers 108 are coupled to a bottom plate of the heat sinks 112 so that heat flowing from the hot heat exchangers 108 to the heat sinks 112. In some embodiments, the heat sinks 112 have fins extending vertically from the bottom plate that are oriented in a same direction as air flow 152 from the fans 103. The heat sinks 112, in some embodiments, include a metal, such as copper, aluminum, or the like. One of skill in the art will recognize various heat sink designs and materials suitable for coupling to the thermoacoustic heat pump 101.

Cool air from the fans 103 transports the heat from the heat sinks 112 and typically out a back side of the servers 160 (top of the motherboard 162). The thermoacoustic heat pumps 101 are each depicted with curves as needed to position the driver 110, the hot heat exchanger 108, the cold heat exchanger 104, and the closed end 109 to be effective. The servers 160 also include CPUs 118 and data storage 122, which is typically non-volatile data storage, such as a solid-state drive, hard disk drive, etc.

In some embodiments, the components 114 being cooled are communication components, such as a peripheral component interconnect express (“PCIe”) cards, network interface cards (NICs”), data storage 122, or other components. In some embodiments, the component 114 being cooled is at a component location in a position where air from the fan 103 is insufficient for a heat load of the component 114. In other embodiments, the components 114 being cooled have air flow from the fans 103, but need more cooling. One of skill in the art will recognize other components 114 to be cooled with a thermoacoustic heat pump 101. While the resonance tube 102 is depicted running across a middle of the component 114 being cooled and the heat sink 112, in other embodiments, the resonance tube 102 is positioned elsewhere on the component 114 and/or heat sink 112.

In various embodiments, the component 114 is located in an area of lower air flow than air flow across the heat sink 112. The heat sinks 112 are depicted as being located over DIMMs 120, which may be appropriate for servers 160 that have a 2U height within a rack. In various embodiments, the heat sinks 112 may be moved closer to or farther away from the fan 103. Where the servers 160 are 1U, there is typically not enough space above the DIMMs for a heat sink 112, which may then be placed elsewhere on the motherboard 162 that is within the air flow 152 from the fans 103.

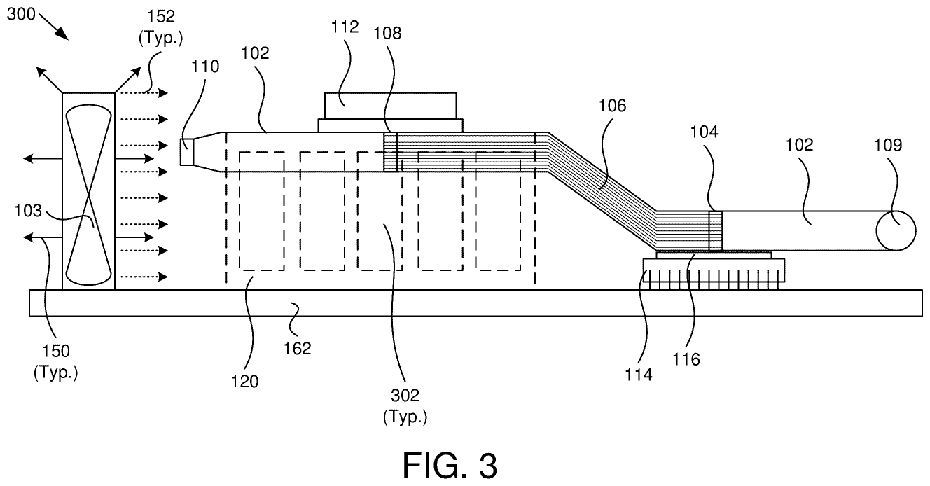

FIG. 3 is a schematic block diagram 300 illustrating a side view of the thermoacoustic heat pump 101 of FIG. 2, according to various embodiments. In some embodiments, the thermoacoustic heat pump 101 has a resonance tube 102 that is positioned just below a top of the DIMMs 120 to be on a bottom side of the heat sink 112. In the embodiments, the resonance tube 102 runs between two DIMMs 120, which are depicted with dashed lines. Memory chips 302 on the DIMMs 120 are also depicted with dashed lines. In other embodiments, the resonance tube 102 extends fully or partially through the bottom plate of the heat sinks 112. In other embodiments, the resonance tube 102 is secured on top of the bottom plate of the heat sink 112 and between fins of the heat sink 112.

In some embodiments, the resonance tube 102 angles downward at an end of the DIMMs to be at an appropriate height to be coupled to a top of a heat spreader 116, which is on top of a component 114 being cooled. In other embodiments, the heat spreader 116 is coupled to a side of the component 114. In other embodiments, the resonance tube 102 runs through a portion of the heat spreader 116 or is in some way integral with the heat spreader 116. The heat spreader 116 coupled to the component 114 and to the cold heat exchanger 104 so that heat from the component 114 is transferred to the cold heat exchanger 104.

The resonance tube 102 is depicted in FIG. 2 with a bend to the right before reaching the closed end 109 of the resonance tube 102. In other embodiments, the resonance tube 112 has a different length, has different turns, etc. to accommodate a desired length to achieve resonance at a chosen frequency. In various embodiments, a distance from the closed end 109 to the component 114 is chosen so the length of the resonance tube 102 corresponds to a resonant frequency of the sound waves in the resonance tube 102 induced by the fan sound frequency.

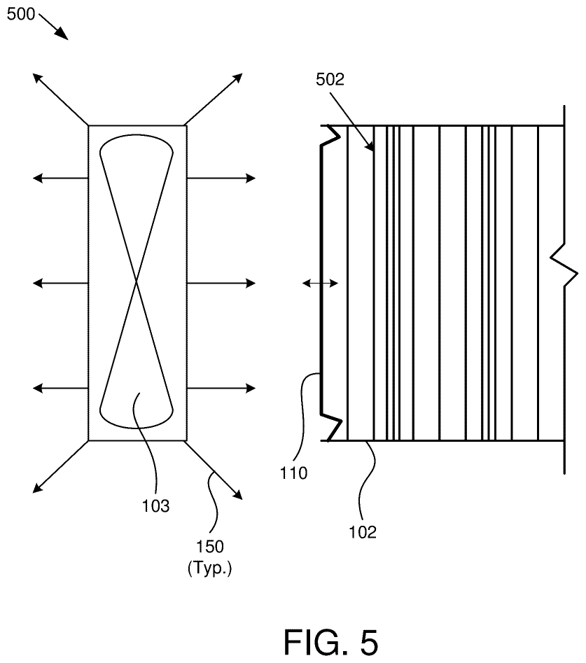

The second end of the resonance tube 102 terminates in a driver 110. The driver 110 is designed to transfer sound energy from the fans 103 to a gas within the resonance tube 102 while maintaining the gas within the resonance tube 102. In some embodiments, the driver 110 is a diaphragm, as explained further with respect to FIG. 5. In other embodiments, the driver 110 is a speaker and microphone system that receives sound at the microphone from the fans 103 and the speaker transfers sound energy to the gas in the resonance tube 102. In other embodiments, the driver 110 is another device capable of transferring sound energy from the fans 103 to the gas within the resonance tube 102. The end of the driver 110 facing the fans 103 is depicted as smaller than a diameter of the resonance tube 102, which is a typical symbol of a driver of a thermoacoustic heat pump. The driver 110 may be smaller than the diameter of the resonance tube 102, may be the same diameter as the resonance tube 102 or larger than the diameter of the resonance tube 102.

FIG. 4 is a schematic block diagram 400 illustrating a cross section view of stack designs of various thermoacoustic pumps 101, according to various embodiments. The top left design 4(a) includes a spiral designed stack 402. In the embodiments, the stack 402 includes a sheet 404 of a material wound around a center rod 408. Spacers 406 maintain spacing of the spiral sheet 404. In various embodiments, the sheet 404 is plastic, reticulated vitreous carbon (“RVC”) foam, mylar, Kapton, Celcor, high impact poly styrene (“HIPS”), polyamid nylon (“PA”), and/or acrylonitrile butadiene styrene (“ABS”) or another material with a low thermal conductivity. In some embodiments, the cold heat exchanger 104 and the hot heat exchanger 108 have a matching design, but are of a material with a higher thermal conductivity, such as copper, aluminum, nickel, tin, or the like. In some embodiments, the center rod 408 and/or the spacers 406 are a nylon filaments, fishing line, or other material with a low thermal conductivity. Spacers 406 of the cold heat exchanger 104 and the hot heat exchanger 108 may be of a different material, such as copper wire.

Another stack 410 4(b) includes parallel plates 412. The plates 412 are depicted running horizontally, but may also run in another direction. A third stack 420 4(c) includes a structure 422 with square shaped channels. Other designs may include honeycomb, rectangular, or other shaped channels. A fourth stack 430 4(d) includes a pin array 432 that include plates with pins that are perpendicular to the plates to provide spacing between the plates. In the various stacks 402, 410, 420, 430, materials are typically low thermal conductivity where the cold heat exchangers 104 and hot heat exchangers 108 typically have a similar design, but include materials that have a higher thermal conductivity to transfer heat from the component 114 and to the heat sink 112. A fifth stack 440 4(c) includes material 442 that is configured in a random array with random channels and materials. In some embodiments, the material includes nylon strands, steel wool, or the like. A random stack 440 typically performs differently than other stacks 402, 410, 420, 430 and design of the resonance tube 102, stack 106, etc. are designed accordingly.

FIG. 5 is a schematic block diagram 500 illustrating a cross section view of a driver 110 for a thermoacoustic heat pump 101 driven by sound of a fan 103, according to various embodiments. The driver 110, in the depicted embodiments, is a diaphragm that moves left and right in response to sound waves 150 from the fan 103. The movement of the diaphragm causes pressure sound waves 502 in a gas in the resonance tube 102 that resonate at a chosen resonant frequency. The resonant frequency, in some embodiments, is chosen based on frequencies from the sound waves 150 of the fan 103. Choosing the length of the resonance tube 102 sets the resonant frequency based on the particular design of the resonance tube 102, such as the shape, diameter, etc. of the resonance tube 102.

FIG. 6 is a schematic block diagram 600 illustrating another thermoacoustic heat pump 602 driven by sound from a fan 103 of a computing device 106 where the thermoacoustic heat pump 602 includes a hemispherical end 604, according to various embodiments. The fan 103 produces sound waves 150 in various directions and air flow 152 in the direction of the thermoacoustic heat pump 602, as described above. The resonance tube 102 includes a driver 110, a hot heat exchanger 108, a stack 106, and a cold heat exchanger 104, which are substantially similar to those described above. The thermoacoustic heat pump 602 includes a portion 606 beyond the cold heat exchanger that with a taper and divergent tube with hemispherical end (“TDH”). The portion 606 is optimized for minimum heat dissipation losses by decreasing the volume. This increases performance and power density. In other embodiments, the resonance tube 102 is shaped differently.

Embodiments may be practiced in other specific forms. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus comprising:
a heat sink in a computing device;
a resonance tube in the computing device extending from a fan and past the heat sink and past a component of the computing device, wherein the resonance tube is thermally coupled to the heat sink and to the component; and
a driver connected at an end of the resonance tube adjacent to the fan, wherein the driver is configured such that sound from the fan moves the driver to induce sound waves within the resonance tube,
wherein a length of the resonance tube is selected to correspond to a fan sound frequency of sound emanating from the fan, wherein sound waves at the fan sound frequency resonate within the resonance tube at the fan sound frequency, and
wherein heat from the component is transferred to the resonance tube and travels in the resonance tube to a location where the heat sink is coupled to the resonance tube and exits to the heat sink.

2. The apparatus of claim 1, wherein the heat sink is positioned within an air flow within the computing device, the air flow configured to stream across the heat sink.

3. The apparatus of claim 2, wherein the air flow across the heat sink originates at the fan.

4. The apparatus of claim 1, further comprising:
a cold heat exchanger within the resonance tube at a component location where the component is coupled to the resonance tube;
a hot heat exchanger within the resonance tube at a heat sink location where the heat sink is coupled to the resonance tube; and
a stack within the resonance tube spanning between the cold heat exchanger and the hot heat exchanger,
wherein the cold heat exchanger, the hot heat exchanger, and the stack each comprise a porous material configured to transfer heat.

5. The apparatus of claim 4, wherein the porous materials of the cold heat exchanger, the hot heat exchanger, and the stack each comprise channels, the channels running in a direction of the length of the resonance tube.

6. The apparatus of claim 5, wherein the porous materials of the cold heat exchanger, the hot heat exchanger, and the stack comprise parallel plates, spiral sheets, rectangular pores, a pin array, a honeycomb, and/or a random array, wherein spaces within the porous materials form the channels.

7. The apparatus of claim 4, wherein the porous materials of the cold heat exchanger, the hot heat exchanger, and the stack comprise plastic, reticulated vitreous carbon (“RVC”) foam, mylar, copper, nickel, stainless steel, molybdenum, tungsten, Kapton, Celcor, high impact poly styrene (“HIPS”), polyamid nylon (“PA”), and/or acrylonitrile butadiene styrene (“ABS”).

8. The apparatus of claim 1, wherein the component comprises one of a hard disk drive, a solid-state drive, a memory card, and a network interface card.

9. The apparatus of claim 1, wherein the resonance tube comprises a gas within the resonance tube.

10. The apparatus of claim 9, wherein the gas is one of air, helium, and nitrogen.

11. The apparatus of claim 1, wherein the driver comprises a diaphragm.

12. The apparatus of claim 1, wherein the driver is adjacent to the fan and the resonance tube extends from the driver to the heat sink and from the heat sink to the component and from the component to a closed end.

13. The apparatus of claim 12, wherein a distance from the closed end to the component is chosen so the length of the resonance tube corresponds to a resonant frequency of the sound waves in the resonance tube induced by the fan sound frequency.

14. The apparatus of claim 12, wherein the closed end of the resonance tube is shaped to reflect the sound waves in the resonance tube.

15. The apparatus of claim 1, wherein the component is located in an area of lower air flow than air flow across the heat sink.

16. An apparatus comprising:
a heat sink in a computing device;
a resonance tube in the computing device extending from a fan and past the heat sink and past a component of the computing device, wherein the resonance tube is thermally coupled to the heat sink and to the component;
a driver connected at an end of the resonance tube adjacent to the fan, wherein sound from the fan moves the driver to induce sound waves within the resonance tube;
a cold heat exchanger within the resonance tube at a component location where the component is coupled to the resonance tube;
a hot heat exchanger within the resonance tube at a heat sink location where the heat sink is coupled to the resonance tube; and
a stack within the resonance tube spanning between the cold heat exchanger and the hot heat exchanger,
wherein the cold heat exchanger, the hot heat exchanger, and the stack each comprise a porous material configured to transfer heat,
wherein a length of the resonance tube is selected to correspond to a fan sound frequency of sound emanating from the fan, wherein sound waves at the fan sound frequency resonate within the resonance tube at the fan sound frequency, and
wherein heat from the component is transferred to the resonance tube and travels in the resonance tube to a location where the heat sink is coupled to the resonance tube and exits to the heat sink.

17. The apparatus of claim 16, wherein the heat sink is positioned within an air flow within the computing device, the air flow configured to stream across the heat sink.

18. The apparatus of claim 16, wherein the porous materials of the cold heat exchanger, the hot heat exchanger, and the stack each comprise channels, the channels running in a direction of the length of the resonance tube.

19. A system comprising:
a computing device comprising a processor;
a fan configured to provide cooling to the processor;
a component within the computing device;
a heat sink within the computing device;
a resonance tube in the computing device extending from the fan and past the heat sink and past the component of the computing device, wherein the resonance tube is thermally coupled to the heat sink and to the component; and
a driver connected at an end of the resonance tube adjacent to the fan, wherein sound from the fan moves the driver to induce sound waves within the resonance tube,
wherein a length of the resonance tube is selected to correspond to a fan sound frequency of sound emanating from the fan, wherein sound waves at the fan sound frequency resonate within the resonance tube at the fan sound frequency, and
wherein heat from the component is transferred to the resonance tube and travels in the resonance tube to a location where the heat sink is coupled to the resonance tube and exits to the heat sink.

20. The system of claim 19, wherein the heat sink is positioned within an air flow within the computing device, the air flow configured to stream across the heat sink.
